(19) United States
(12) Patent Application Publication
(10) Pub. No.: US 2010/0045350 A1
(43) Pub. Date: Feb. 25, 2010

(54) Semiconductor Device and Amplification Device Generating Triangular Wave Synchronized with Clock Signal

(75) Inventors: Koji Saito, Kyoto-shi (JP); Kuniyuki Kubo, Kyoto-shi (JP)

Correspondence Address: FISH & RICHARDSON P.C., P.O. BOX 1022, MINNEAPOLIS, MN, 55440-1022, US

(73) Assignee: Rohm Co., Ltd., Kyoto (JP)

(21) Appl. No.: 12/544,336

(22) Filed: Aug. 20, 2009

(30) Foreign Application Priority Data
Aug. 20, 2008 (JP) 2008-211716

(51) Int. Cl. H03K 4/06; H03K 4/90

(52) U.S. Cl. 327/132; 327/136; 327/137

(57) ABSTRACT

A semiconductor device includes a current control circuit for outputting and sinking a current in synchronization with a received clock signal; and a current/voltage conversion circuit having a first capacitor charged and discharged by the current control circuit outputting and sinking the current, respectively, and outputting a triangular wave based on the charge stored in the first capacitor.

### BACKGROUND OF THE INVENTION

1. Field of the Invention

The present invention relates to a semiconductor device and an amplification device, and particularly to a semiconductor device and an amplification device generating a triangular wave synchronized with a clock signal.

2. Description of the Background Art

The so-called class D amplifier for amplifying power using a switching circuit is known. The class D amplifier includes, for example, an integrator, a triangular wave generating circuit, a comparator comparing an output of the integrator with an output of the triangular wave generating circuit, and a current control circuit for outputting a current based on the signal received from the comparator. The output of the comparator is fed back to the input of the integrator.

As an example of the triangular wave generating circuit, “Design and Fabrication of Class D/Digital Amplifier” (pp. 60-61) authored by Jun Honda and issued by CQ Publishing Co., Ltd. on 2004 (Non-Patent Document 1), for example, discloses a configuration in which a triangular wave generating circuit includes a differential amplifier, an integration circuit configured of a resistor and a capacitor, and a comparator having hysteresis.

Furthermore, as an example of the triangular wave generating circuit in the class D amplifier, Japanese Patent Laying-Open No. 2006-020177 (Patent Document 1), for example, discloses a configuration in which a triangular wave generating circuit used in the class D amplifier provided with a switching amplification stage for performing switching amplification of the pulse-width modulation output obtained by performing pulse-width modulation of the input signal includes first constant current means for outputting a first constant current proportional to the positive power supply voltage of the switching amplification stage, second constant current means for outputting a second constant current proportional to the negative power supply voltage of the switching amplification stage, constant current selection means for periodically and alternately selecting the first and second constant currents with a high impedance element, first integration means for outputting an integrated output as a triangular wave, the first integration means having a capacity charged with the selected constant current interposed between the input terminal and the output terminal of the amplifier, and second integration means for integrating the output of the first integration means and negatively feeding back the integrated output to the input terminal of the first integration means as a phase correction instruction for the triangular wave.

However, in the case where the triangular wave generating circuit disclosed in each of Non-Patent Document 1 and Patent Document 1 is used along with a digital circuit, the interference of a system clock and the like produces beat noise, which may lead to deterioration of the performance.

### SUMMARY OF THE INVENTION

An object of the present invention is to provide a semiconductor device and an amplification device which are capable of generating a triangular wave and preventing performance deterioration caused by interference of a system clock and the like.

The semiconductor device according to an aspect of the present invention includes a current control circuit for outputting and sinking a current in synchronization with a received clock signal; and a current/voltage conversion circuit having a first capacitor charged and discharged by the current control circuit outputting and sinking the current, respectively, and outputting a triangular wave based on a charge stored in the first capacitor.

Preferably, the current/voltage conversion circuit includes a first differential amplifier having a first input terminal coupled to the current control circuit and a first end of the first capacitor, a second input terminal receiving a first reference voltage and an output terminal coupled to a second end of the first capacitor; and a first resistor connected between the current control circuit and a coupling point between the first input terminal of the first differential amplifier and the first end of the first capacitor.

More preferably, the semiconductor device further includes a second differential amplifier having a first input terminal coupled to the output terminal of the first differential amplifier, a second input terminal receiving a second reference voltage and an output terminal; a second capacitor connected between the first input terminal of the second differential amplifier and the output terminal of the second differential amplifier; and a second resistor connected between a coupling point between one end of the second capacitor and the first input terminal of the second differential amplifier, and a coupling point between the second end of the first capacitor and the output terminal of the first differential amplifier. The first reference voltage is output from the output terminal of the second differential amplifier.

More preferably, a resistance value of the first resistor is variable.

Preferably, the semiconductor device further includes a comparison circuit for comparing the triangular wave with a second reference voltage, and the current/voltage conversion circuit changes a direct current level of the triangular wave based on a comparison result by the comparison circuit.

Preferably, the current control circuit includes a first transistor of a first conduction type having a control electrode receiving the clock signal, a first conductive electrode coupled to a node supplied with a power supply voltage and a second conductive electrode coupled to the first capacitor; and a second transistor of a second conduction type having a control electrode receiving the clock signal, a first conductive electrode coupled to a node supplied with a ground voltage and a second conductive electrode coupled to the first capacitor.

Furthermore, an amplification device according to an aspect of the present invention includes a D/A (Digital-to-Analog) converter for converting a digital signal into an analog signal; an integration circuit for integrating and outputting the converted analog signal; a triangular wave generating circuit for generating a triangular wave; a comparator for comparing the integrated analog signal with the triangular wave and outputting a signal representing a comparison result; and a first current control circuit for outputting a current based on the signal received from the comparator. The triangular wave generating circuit includes a second current control circuit for outputting and sinking a current in synchronization with a received clock signal; and a current/voltage conversion circuit having a first capacitor charged and discharged by the second current control circuit outputting and sinking the current, respectively, and outputting the triangular wave based on a charge stored in the first capacitor.

According to the present invention, a triangular wave can be generated to thereby prevent performance deterioration caused by interference of a system clock and the like.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram of the configuration of a motor system according to a first embodiment of the present invention.

FIG. 2 is a diagram of the configuration of a triangular wave generating circuit according to the first embodiment of the present invention.

FIG. 3 is a waveform diagram showing the operation of the triangular wave generating circuit according to the first embodiment of the present invention.

FIG. 4 is a diagram of the configuration of a triangular wave generating circuit according to a second embodiment of the present invention.

### DESCRIPTION OF THE PREFERRED EMBODIMENTS

The embodiments of the present invention will be hereinafter described with reference to the accompanying drawings, in which the same or corresponding components are designated by the same reference characters, and description thereof will not be repeated.

### First Embodiment

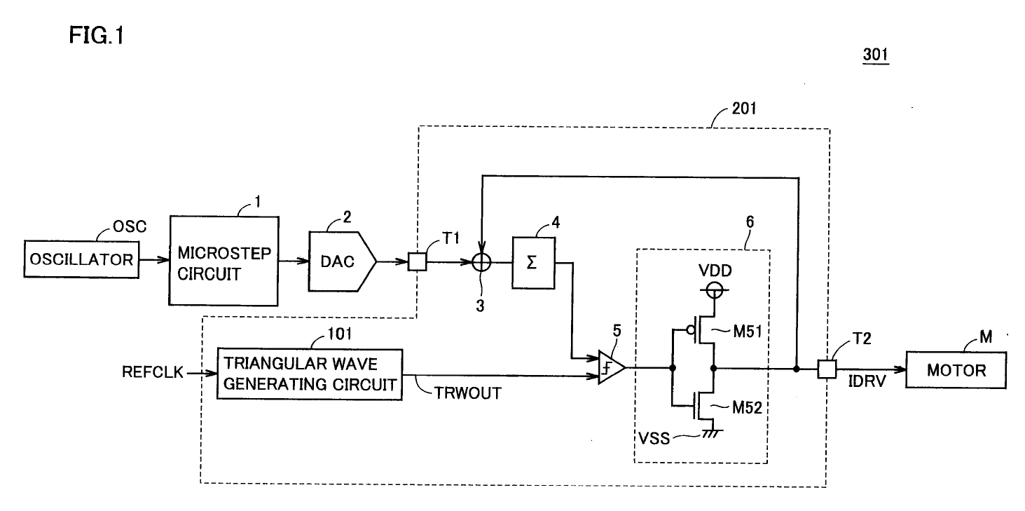

FIG. 1 is a diagram of the configuration of a motor system according to a first embodiment of the present invention.

Referring to FIG. 1, a motor system 301 includes an oscillator OSC, a microstep circuit 1, a D/A (Digital-to-Analog) converter (DAC) 2, an amplification device 201, and a motor M. Amplification device 201 includes an arithmetic unit 3, an integrator 4, a comparator 5, a current control circuit 6, and a triangular wave generating circuit 101.

Microstep circuit 1 calculates a drive current value used for microstep-driving motor M based on the oscillation signal received from oscillator OSC, and outputs the drive data showing this drive current value to D/A converter 2.

D/A converter 2 converts the drive data received from microstep circuit 1 into an analog signal, and outputs the signal to amplification device 201.

Amplification device 201 amplifies the analog signal received from D/A converter 2 to generate a drive current IDRV, and supplies the current to motor M. Amplification device 201 is included in one integrated circuit having, for example, external terminals T1 and T2.

More specifically, arithmetic unit 3 adds the analog signal received from D/A converter 2 via external terminal T1 and the signal fed back from current control circuit 6, and outputs the result to integrator 4.

Integrator 4 integrates the analog signal received from arithmetic unit 3 and outputs the result to comparator 5. Triangular wave generating circuit 101 generates and outputs a triangular wave TRWOUT to comparator 5.

Comparator 5 compares the analog signal received from integrator 4 with triangular wave TRWOUT received from triangular wave generating circuit 101, and outputs the signal representing the comparison result.

Current control circuit 6 outputs drive current IDRV based on the signal received from comparator 5. Drive current IDRV is supplied to motor M via external terminal T2.

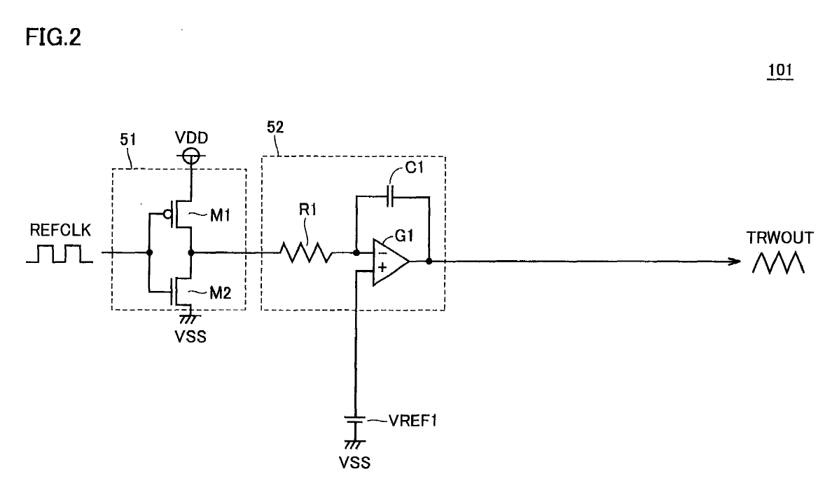

FIG. 2 is a diagram of the configuration of the triangular wave generating circuit according to the first embodiment of the present invention.

Referring to FIG. 2, triangular wave generating circuit 101 includes a current control circuit 51 and a current/voltage conversion circuit 52.

Current control circuit 51 includes a P-channel MOS (Metal Oxide Semiconductor) transistor M1 and an N-channel MOS transistor M2. Current/voltage conversion circuit 52 includes a differential amplifier G1, a capacitor C1 and a resistor R1.

P-channel MOS transistor M1 includes a gate receiving a reference clock REFCLK, a source coupled to a node VDD supplied with a power supply voltage, and a drain coupled to capacitor C1. N-channel MOS transistor M2 includes a gate receiving reference clock REFCLK, a source coupled to a node VSS supplied with a ground voltage, and a drain coupled to capacitor C1.

Differential amplifier G1 has an inversion input terminal coupled to current control circuit 51 and the first end of capacitor C1, a non-inversion input terminal receiving a reference voltage VREF1, and an output terminal coupled to the second end of capacitor C1. Resistor R1 is connected between the node connecting a drain of P-channel MOS transistor M1 and a drain of N-channel MOS transistor M2, and the node connecting the inversion input terminal of differential amplifier G1 and the first end of capacitor C1.

Current control circuit 51 outputs and sinks a current in synchronization with reference clock REFCLK.

Current/voltage conversion circuit 52 serving as an integrator includes capacitor C1 charged and discharged by current control circuit 51 outputting and sinking the current, respectively, and outputs triangular wave TRWOUT based on the charge stored in capacitor C1.

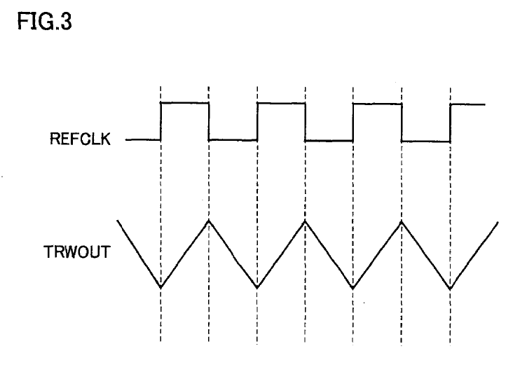

FIG. 3 is a waveform diagram showing the operation of the triangular wave generating circuit according to the first embodiment of the present invention.

Referring to FIG. 3, when reference clock REFCLK transitions from a logic high level to a logic low level, the current flows from node VDD through N-channel MOS transistor M1 into current/voltage conversion circuit 52. Consequently, capacitor C1 is charged and the level of output voltage TRWOUT is lowered. Furthermore, when reference clock REFCLK transitions from a logic low level to a logic high level, capacitor C1 is discharged and the current flows from current/voltage conversion circuit 52 through N-channel MOS transistor M2 into node VSS. This raises the level of output voltage TRWOUT.

In other words, the level and cycle of triangular wave TRWOUT can be controlled by controlling the frequency of reference clock REFCLK.

In the case where the frequency of reference clock REFCLK is lowered, triangular wave TRWOUT may increase in amplitude to cause distortion. However, in the triangular wave generating circuit according to the first embodiment of the present invention, the resistance value of resistor R1 is variable. This allows the amplitude of triangular wave TRWOUT to be adjusted. For example, since the amplitude of triangular wave TRWOUT can be reduced by increasing the resistance value of resistor R1, distortion of triangular wave TRWOUT can be prevented.

In the case where the triangular wave generating circuit disclosed in each of Non-Patent Document 1 and Patent Document 1 is used along with a digital circuit, the interference of a system clock and the like causes beat noise, which may lead to deterioration of the performance.

However, in the triangular wave generating circuit according to the first embodiment of the present invention, current control circuit 51 outputs and sinks a current in synchronization with reference clock REFCLK. Current/voltage conversion circuit 52 includes capacitor C1 charged and discharged by current control circuit 51 outputting and sinking the current, respectively, and outputs triangular wave TRWOUT based on the charge stored in capacitor C1. According to this configuration, triangular wave TRWOUT synchronized with reference clock REFCLK can be generated. Therefore, in the triangular wave generating circuit according to the first embodiment of the present invention, beat noise occurring due to interference of a system clock and the like can be prevented, and thus, performance deterioration can be prevented.

Another embodiment of the present invention will be hereinafter described with reference to the accompanying drawings, in which the same or corresponding components are designated by the same reference characters, and description thereof will not be repeated.

### Second Embodiment

The present embodiment relates to a triangular wave generating circuit additionally provided with a function of adjusting the level of the triangular wave as compared with the triangular wave generating circuit according to the first embodiment. The triangular wave generating circuit according to the present embodiment is the same as that according to the first embodiment except for features as described below.

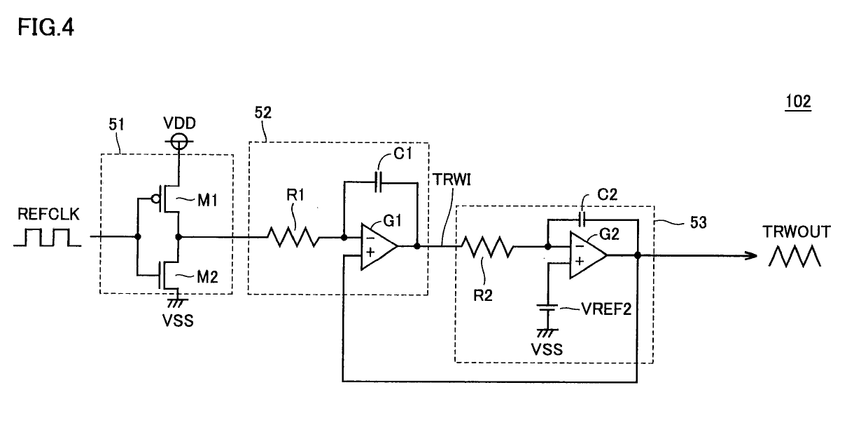

FIG. 4 is a diagram of the configuration of a triangular wave generating circuit according to the second embodiment of the present invention.

Referring to FIG. 4, a triangular wave generating circuit 102 includes a current control circuit 51, a current/voltage conversion circuit 52, and a comparison circuit 53.

Current control circuit 51 includes a P-channel MOS transistor M1 and an N-channel MOS transistor M2. Current/voltage conversion circuit 52 includes a differential amplifier G1, a capacitor C1 and a resistor R1. Comparison circuit 53 includes a differential amplifier G2, a resistor R2 and a capacitor C2.

Differential amplifier G1 has an inversion input terminal coupled to current control circuit 51 and the first end of capacitor C1, a non-inversion input terminal receiving a reference voltage VREF1, and an output terminal coupled to the second end of capacitor C1. Resistor R1 is connected between the node connecting a drain of P-channel MOS transistor M1 and a drain of N-channel MOS transistor M2, and the node connecting the inversion input terminal of differential amplifier G1 and the first end of capacitor C1.

Differential amplifier G2 has an inversion input terminal coupled to the output terminal of differential amplifier G1, a non-inversion input terminal receiving a reference voltage VREF2, and an output terminal coupled to the non-inversion input terminal of differential amplifier G1. Resistor R2 is connected between the node connecting the output terminal of differential amplifier G1 and the second end of capacitor C1, and the node connecting the inversion input terminal of differential amplifier G2 and the first end of capacitor C2. Capacitor C2 is connected between the output terminal of differential amplifier G2 and the node connecting the inversion input terminal of differential amplifier G2 and resistor R2.

Current control circuit 51 outputs and sinks the current in synchronization with a reference clock REFCLK.

Current/voltage conversion circuit 52 serving as an integrator includes capacitor C1 charged and discharged by current control circuit 51 outputting and sinking the current, respectively, and generates a triangular wave TRWI based on the charge stored in capacitor C1 to output the same to comparison circuit 53.

Comparison circuit 53 compares the output voltage of current/voltage conversion circuit 52, that is, triangular wave TRWI with reference voltage VREF2. Current/voltage conversion circuit 52 changes the direct current level of triangular wave TRWI based on the comparison result by comparison circuit 53, and outputs it as a triangular wave TRWOUT.

Differential amplifier G2 outputs the voltage showing the difference between triangular wave TRWI and reference voltage VREF2 to the non-inversion input terminal of differential amplifier G1. Consequently, the direct current level of output voltage TRWOUT is fed back to current/voltage conversion circuit 52, with the result that the operating point of triangular wave generating circuit 102 can be prevented from being displaced over time.

Furthermore, in order to reduce distortion of triangular wave TRWOUT, resistor R2 is set to have a resistance value greater than that of resistor R1.

Since other configuration and operation are the same as those of the triangular wave generating circuit according to the first embodiment, detailed description thereof will not be repeated.

Therefore, as in the triangular wave generating circuit according to the first embodiment of the present invention, the triangular wave generating circuit according to the second embodiment of the present invention can prevent the beat noise occurring due to interference of a system clock and the like, and thus can prevent the performance deterioration.

Although the triangular wave generating circuit according to the second embodiment of the present invention is configured in such a manner that the output terminal of differential amplifier G2 and the non-inversion input terminal of differential amplifier G1 are directly connected to each other, the configuration is not limited thereto. The triangular wave generating circuit may be configured in such a manner that a resistor and the like is connected between the non-inversion input terminal of differential amplifier G1 and the node connecting the output terminal of differential amplifier G2 and the second end of capacitor C2.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device comprising:
a current control circuit for outputting and sinking a current in synchronization with a received clock signal; and
a current/voltage conversion circuit having a first capacitor charged and discharged by said current control circuit outputting and sinking the current, respectively, and outputting a triangular wave based on a charge stored in said first capacitor.

2. The semiconductor device according to claim 1, wherein
said current/voltage conversion circuit includes
a first differential amplifier having a first input terminal coupled to said current control circuit and a first end of said first capacitor, a second input terminal receiving a first reference voltage and an output terminal coupled to a second end of said first capacitor, and
a first resistor connected between said current control circuit and a coupling point between the first input terminal of said first differential amplifier and the first end of said first capacitor.

3. The semiconductor device according to claim 2, further comprising:
a second differential amplifier having a first input terminal coupled to the output terminal of said first differential amplifier, a second input terminal receiving a second reference voltage and an output terminal;
a second capacitor connected between the first input terminal of said second differential amplifier and the output terminal of said second differential amplifier; and
a second resistor connected between a coupling point between one end of said second capacitor and the first input terminal of said second differential amplifier, and a coupling point between the second end of said first capacitor and the output terminal of said first differential amplifier, wherein
said first reference voltage is output from the output terminal of said second differential amplifier.

4. The semiconductor device according to claim 2, wherein a resistance value of said first resistor is variable.

5. The semiconductor device according to claim 1, further comprising a comparison circuit for comparing said triangular wave with a second reference voltage, wherein
said current/voltage conversion circuit changes a direct current level of the triangular wave based on a comparison result by said comparison circuit.

6. The semiconductor device according to claim 1, wherein
said current control circuit includes
a first transistor of a first conduction type having a control electrode receiving said clock signal, a first conductive electrode coupled to a node supplied with a power supply voltage and a second conductive electrode coupled to said first capacitor, and
a second transistor of a second conduction type having a control electrode receiving said clock signal, a first conductive electrode coupled to a node supplied with a ground voltage and a second conductive electrode coupled to said first capacitor.

7. An amplification device comprising:
a D/A converter for converting a digital signal into an analog signal;
an integration circuit for integrating and outputting said converted analog signal;
a triangular wave generating circuit for generating a triangular wave;
a comparator for comparing said integrated analog signal with said triangular wave and outputting a signal representing a comparison result; and
a first current control circuit for outputting a current based on the signal received from said comparator, and
said triangular wave generating circuit including
a second current control circuit for outputting and sinking a current in synchronization with a received clock signal, and
a current/voltage conversion circuit having a first capacitor charged and discharged by said second current control circuit outputting and sinking the current, respectively, and outputting said triangular wave based on a charge stored in said first capacitor.
